(19) United States
(12) Patent Application Publication
(10) Pub. No.: US 2017/0158495 A1
(43) Pub. Date: Jun. 8, 2017

(54) LASER RESEAL INCLUDING DIFFERENT CAP MATERIALS

(71) Applicant: Robert Bosch GmbH, Stuttgart (DE)

(72) Inventors: Achim Breitling, Reutlingen (DE); Frank Reichenbach, Wannweil (DE); Jens Frey, Filderstadt (DE); Jochen Reinmuth, Reutlingen (DE); Julia Amthor, Reutlingen (DE)

(21) Appl. No.: 15/369,038

(22) Filed: Dec. 5, 2016

(30) Foreign Application Priority Data
Dec. 8, 2015 (DE) 102015224481.4

(51) Int. Cl. B81C 1/00; B81B 7/00

(52) U.S. Cl. CPC B81C 1/00277; B81B 7/0035; B81C 2203/0145; B81B 2201/0242; B81B 2201/0235

(57) ABSTRACT

A method for manufacturing a micromechanical component including a substrate, and a cap connected to the substrate, the cap, together with the substrate, encloses a cavity, a pressure prevailing and a gas mixture having a first chemical composition being enclosed in the cavity. An access opening connecting the cavity to surroundings of the micromechanical component is formed in the substrate or in the cap. The pressure and/or the chemical composition is adjusted in the cavity. The access opening is sealed by introducing energy or heat into an absorbing part of the substrate or the cap with the aid of a laser. A first crystalline, amorphous, nanocrystalline, or polycrystalline layer is deposited or grown on a surface of the substrate or of the cap, and/or a substrate including a second crystalline, amorphous, nanocrystalline, and/or polycrystalline layer, and/or a cap including the second crystalline, amorphous, nanocrystalline, and/or polycrystalline layer is provided.

### CROSS REFERENCE

The present application claims the benefit under 35 U.S.C. §119 of German Patent Application No. DE 102015224481.4 filed on Dec. 8, 2015, which is expressly incorporated herein by reference in its entirety.

### BACKGROUND INFORMATION

A method is described in PCT Application No. WO 2015/120939 A1 in which, when a certain internal pressure is desired in a cavity of a micromechanical component or a gas mixture having a certain chemical composition is to be enclosed in the cavity, the internal pressure or the chemical composition is frequently adjusted during capping of the micromechanical component or during the bonding process between a substrate wafer and a cap wafer. During capping, for example, a cap is connected to a substrate, whereby the cap and the substrate together enclose the cavity. By adjusting the atmosphere or the pressure and/or the chemical composition of the gas mixture present in the surroundings during capping, it is thus possible to adjust the certain internal pressure and/or the certain chemical composition in the cavity.

With the aid of the method described in PCT Application No. WO 2015/120939 A1, an internal pressure may be adjusted in a targeted way in a cavity of a micromechanical component. It is in particular possible with the aid of this method to manufacture a micromechanical component having a first cavity, a first pressure and a first chemical composition being adjustable in the first cavity, which differ from a second pressure and a second chemical composition at the time of capping.

In the method for targeted adjusting of an internal pressure in a cavity of a micromechanical component according to PCT Application No. WO 2015/120939 A1, a narrow access channel to the cavity is created in the cap or in the cap wafer, or in the substrate or in the sensor wafer. Subsequently, the cavity is flooded with the desired gas and the desired internal pressure via the access channel. Finally, the area around the access channel is locally heated with the aid of a laser, the substrate material liquefies locally and hermetically seals the access channel during solidification.

### SUMMARY

It is an object of the present invention to provide a method for manufacturing a micromechanical component which is mechanically robust and has a long service life compared to the related art, in a simple and cost-effective manner compared to the related art. It is a further object of the present invention to provide a micromechanical component which is compact, mechanically robust and has a long service life compared to the related art. According to the present invention, this applies in particular to a micromechanical component including one (first) cavity. With the aid of the method according to the present invention and the micromechanical component according to the present invention, it is furthermore also possible to implement a micromechanical component in which a first pressure and a first chemical composition may be adjusted in the first cavity, and a second pressure and a second chemical composition may be adjusted in a second cavity. For example, such a method for manufacturing micromechanical components is provided, for which it is advantageous if a first pressure is enclosed in a first cavity and a second pressure is enclosed in a second cavity, the first pressure being different from the second pressure. This is the case, for example, when a first sensor unit for rotation rate measurement and a second sensor unit for acceleration measurement are to be integrated into a micromechanical component.

The object may be achieved in accordance with example embodiments of the present invention by providing

in a fourth method step, a first crystalline layer or a first amorphous layer or a first nanocrystalline layer or a first polycrystalline layer is deposited on or grown on a surface of the substrate or of the cap and/or

in a fifth method step, a substrate including a second crystalline layer and/or a second amorphous layer and/or a second nanocrystalline layer and/or a second polycrystalline layer or a cap including the second crystalline layer and/or the second amorphous layer and/or the second nanocrystalline layer and/or the second polycrystalline layer is provided.

In this way, a method for manufacturing a micromechanical component is provided in a simple and cost-effective manner, with which the resistance to crack formation and/or crack propagation in the vicinity of a material area of the substrate or of the cap, which in the third method step transitions into a liquid aggregate state and after the third method step transitions into a solid aggregate state and seals the access opening, may be increased with the aid of targeted adjustment of the crystallinity of the materials used.

An increased resistance to crack formation and/or crack propagation is achieved, for example, in that the grain boundaries of polycrystalline layers or of a polycrystalline substrate act as a barrier against the propagation of cracks. Micro-cracks in particular are unable or able only with increased intensity to propagate along the crystalline axis through the entire seal or material area. Instead, micro-cracks stop at the grain boundary or at the grain boundaries. In this way, a tearing of the seal is prevented or substantially hindered. An increased resistance to crack formation is also achieved, for example, in that a first stress, which counteracts or compensates for a second stress occurring in the seal or in the material area, or emanating from the seal or the material area, is produced or created or acts as a result of application of the first crystalline, amorphous, nanocrystalline or polycrystalline layer. The first stress is a compressive stress, for example.

In addition, it is less problematic with the method according to the present invention if the substrate material is only heated locally, and the heated material contracts relative to its surroundings, both during solidification and during cooling. It is also less problematic that tensile stresses may develop in the sealing area. Finally, a spontaneously occurring crack formation depending on the stress and material and a crack formation during thermal or mechanical loading of the micromechanical component is also less likely during the further processing or in the field.

Thus, a method for manufacturing a micromechanical component or an arrangement is provided, with which a sealing of a channel is producible via local fusion, the method allowing for a preferably low propensity to crack formation in the micromechanical component.

In connection with the present invention, the term “micromechanical component” is to be understood in that the term encompasses both micromechanical components and microelectromechanical components.

In addition, the term “crystalline” is understood in conjunction with the present invention to mean “monocrystalline” or “single crystalline”. Thus, in conjunction with the present invention, the use of the term “crystalline” means a single crystal or monocrystal or a macroscopic crystal, the atoms or molecules of which form a continuous uniform homogenous crystal lattice. In other words, the term “crystalline” means that essentially all distances of each atom relative to its neighboring atoms are clearly defined. In conjunction with the present invention, “crystalline” is understood, in particular, to mean that the potentially theoretical crystalline sizes or grain sizes are greater than 1 cm or are infinite. The terms “polycrystalline” and “nanocrystalline” are understood in conjunction with the present invention to mean that a crystalline solid body is meant, which includes a plurality of individual crystals or crystallites or grains, the grains being separated from one another by grain boundaries. In conjunction with the present invention, “polycrystalline” is understood, in particular, to mean that the crystallite sizes or grain sizes range from 1 μm to 1 cm. In addition, “nanocrystalline” is understood in conjunction with the present invention to mean, in particular, that the crystallite sizes or grain sizes are smaller than 1 μm. Furthermore, the term “amorphous” is understood in conjunction with the present invention to mean, in particular, that the atoms of an amorphous layer or of an amorphous material merely have a near-order but not a far-order. In other words, “amorphous” means that the distance of each atom is clearly defined only relative to its first closest neighboring atoms, but not to its second or further closest neighboring atoms. The present invention is preferably provided for a micromechanical component including a cavity or its manufacture. However, the present invention is also provided, for example, for a micromechanical component having two cavities, or having more than two, i.e., three, four, five, six or more than six, cavities.

The access opening is preferably sealed by introducing energy or heat with the aid of a laser into a part of the substrate or of the cap which absorbs this energy or this heat. Energy or heat is preferably introduced chronologically in succession into the respective absorbing part of the substrate or of the cap of multiple micromechanical components, which are manufactured together on a wafer, for example. However, alternatively, it is also possible to introduce the energy or heat simultaneously into the respective absorbing part of the substrate or of the cap of multiple micromechanical components, for example using multiple laser beams or laser devices.

Advantageous embodiments and refinements of the present invention may be derived from the description herein with reference to the figures.

According to one preferred refinement, it is provided that the cap, together with the substrate, encloses a second cavity, a second pressure prevailing and a second gas mixture having a second chemical composition being enclosed in the second cavity.

According to one preferred refinement, it is provided that in a sixth method step, a third crystalline layer or a third amorphous layer or a third nanocrystalline layer or a third polycrystalline layer is deposited on or grown on the first crystalline layer or on the first amorphous layer or on the first nanocrystalline layer or on the first polycrystalline layer.

According to one preferred refinement, it is provided that in a seventh method step, a fourth crystalline layer or a fourth amorphous layer or a fourth nanocrystalline layer or a fourth polycrystalline layer is deposited on or grown on the third crystalline layer or on the third amorphous layer or on the third nanocrystalline layer or on the third polycrystalline layer.

According to one preferred refinement, it is provided that in an eighth method step, a fifth crystalline layer or a fifth amorphous layer or a fifth nanocrystalline layer or a fifth polycrystalline layer is deposited on or grown on the fourth crystalline layer or on the fourth amorphous layer or on the fourth nanocrystalline layer or on the fourth polycrystalline layer.

According to one preferred refinement, it is provided that in an eleventh method step, additional crystalline layers and/or additional amorphous layers and/or additional nanocrystalline layers and/or additional polycrystalline layers are each deposited on or grown on a crystalline layer or on an amorphous layer or on a nanocrystalline layer or on a polycrystalline layer.

By applying a layer or a layer packet having a certain crystallinity, it is possible to adjust the layer stresses, preferably compressive stresses, in such a way that the stresses occurring in the material area or in the seal may be compensated for.

According to one preferred refinement, it is provided that a layer facing the surroundings of the micromechanical component has a low melting temperature compared to the other layers. This advantageously makes it possible for the layer facing the surroundings of the micromechanical component to be fused in a targeted manner, for example, in the third method step.

According to one preferred refinement, it is provided that in a ninth method step

the substrate or the cap and/or

the first crystalline layer or the first amorphous layer or the first nanocrystalline layer or the first polycrystalline layer and/or

the second crystalline layer and/or the second amorphous layer and/or the second nanocrystalline layer and/or the second polycrystalline layer and/or

the third crystalline layer or the third amorphous layer or the third nanocrystalline layer or the third polycrystalline layer and/or

the fourth crystalline layer or the fourth amorphous layer or the fourth nanocrystalline layer or the fourth polycrystalline layer and/or

the fifth crystalline layer or the fifth amorphous layer or the fifth nanocrystalline layer or the fifth polycrystalline layer

are doped. Thus, an increased resistance to crack formation is advantageously achieved by the doping of the material. As a result of the doping, the crystalline structure of the material or of the layers is changed, for example. A changed crystalline structure or material structure may, for example, make the material more resistant to crack formation.

According to one preferred refinement, it is provided that in a tenth method step, an oxide situated at least partially on and/or at least partially in

the substrate or the cap and/or

the first crystalline layer or the first amorphous layer or the first nanocrystalline layer or the first polycrystalline layer and/or

the second crystalline layer and/or the second amorphous layer and/or the second nanocrystalline layer and/or the second polycrystalline layer and/or

the third crystalline layer or the third amorphous layer or the third nanocrystalline layer or the third polycrystalline layer and/or

the fourth crystalline layer or the fourth amorphous layer or the fourth nanocrystalline layer or the fourth polycrystalline layer and/or

the fifth crystalline layer or the fifth amorphous layer or the fifth nanocrystalline layer or the fifth polycrystalline layer is removed and/or

the substrate or the cap and/or

the first crystalline layer or the first amorphous layer or the first nanocrystalline layer or the first polycrystalline layer and/or

the second crystalline layer and/or the second amorphous layer and/or the second nanocrystalline layer and/or the second polycrystalline layer and/or

the third crystalline layer or the third amorphous layer or the third nanocrystalline layer or the third polycrystalline layer and/or

the fourth crystalline layer or the fourth amorphous layer or the fourth nanocrystalline layer or the fourth polycrystalline layer and/or

the fifth crystalline layer or the fifth amorphous layer or the fifth nanocrystalline layer or the fifth polycrystalline layer is passivated against oxidation. This allows the defective atoms, which promote the appearance of a crack, to be reduced, for example. In this way the resistance to crack formation is increased.

Additional subject matter of the present invention is a micromechanical component including a substrate and a cap which is connected to the substrate and, together with the substrate, encloses a first cavity, a first pressure prevailing and a first gas mixture having a first chemical composition being enclosed in the first cavity, the substrate or the cap including a sealed access opening

the micromechanical component including a first crystalline layer or first amorphous layer or first nanocrystalline layer or first polycrystalline layer deposited on or grown on a surface of the substrate or of the cap and/or

the substrate or the cap including a second crystalline layer and/or second amorphous layer and/or second nanocrystalline layer and/or second polycrystalline layer. In this way, a compact, mechanically robust and cost-effective micromechanical component having an adjusted first pressure is advantageously provided. The above-mentioned advantages of the method according to the present invention apply correspondingly also to the micromechanical component according to the present invention.

According to one preferred refinement, it is provided that the micromechanical component includes a third crystalline layer or third amorphous layer or third nanocrystalline layer or third polycrystalline layer deposited on or grown on the first crystalline layer or on the first amorphous layer or on the first nanocrystalline layer or on the first polycrystalline layer. As a result, it is possible to advantageously adjust the layer stresses, preferably compressive stresses, in such a way that the stresses occurring in the material area or in the seal may be compensated for.

According to one preferred refinement, it is provided that the cap, together with the substrate, encloses a second cavity, a second pressure prevailing and a second gas mixture having a second chemical composition being enclosed in the second cavity.

In this way, a compact, mechanically robust and cost-effective micromechanical component having an adjusted first pressure and second pressure is advantageously provided.

According to one preferred refinement, it is provided that the first pressure is lower than the second pressure, a first sensor unit for rotation rate measurement being situated in the first cavity, and a second sensor unit for acceleration measurement being situated in the second cavity. In this way, a mechanically robust micromechanical component for rotation rate measurement and acceleration measurement, having optimal operating conditions for both the first sensor unit and the second sensor unit, is advantageously provided.

### BRIEF DESCRIPTION OF THE DRAWINGS

FIG. 1 shows a micromechanical component having an open access opening according to one exemplary specific embodiment of the present invention in a schematic representation.

FIG. 2 shows the micromechanical component according to FIG. 1 having a sealed access opening in a schematic representation.

FIG. 3 shows a method for manufacturing a micromechanical component according to one exemplary specific embodiment of the present invention in a schematic representation.

### DETAILED DESCRIPTION OF EXAMPLE EMBODIMENTS

Identical parts are denoted by the same reference numerals in the various figures and are therefore generally also cited or mentioned only once.

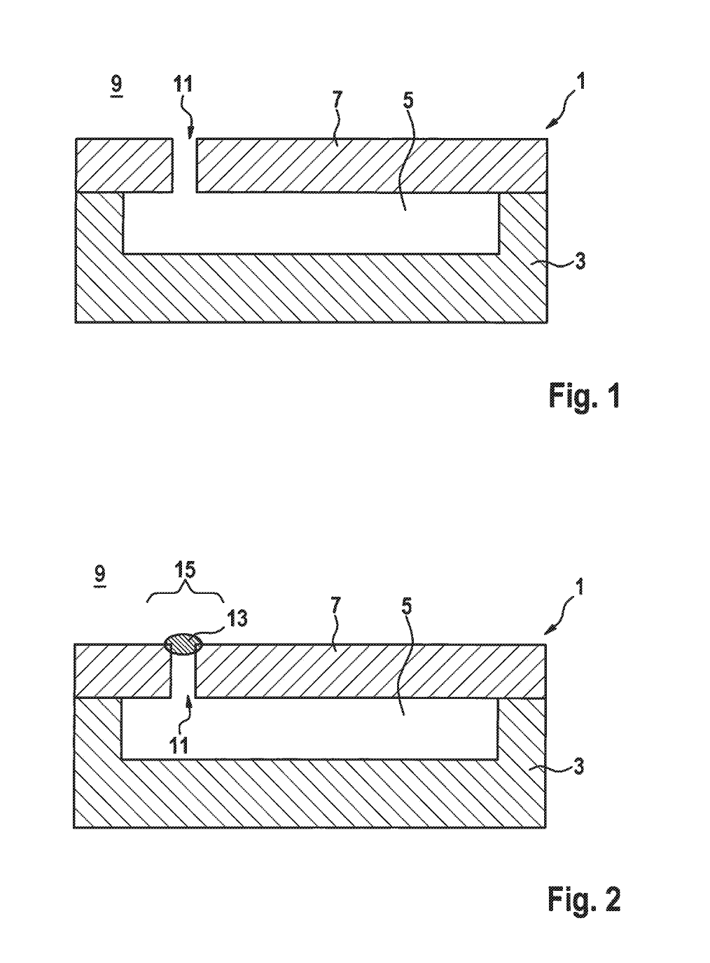

FIG. 1 and FIG. 2 show a schematic representation of a micromechanical component 1 having an open access opening 11 in FIG. 1, and having a sealed access opening 11 in FIG. 2, according to one exemplary specific embodiment of the present invention. Micromechanical component 1 includes a substrate 3 and a cap 7. Substrate 3 and cap 7 are, preferably hermetically, connected to one another and together enclose a first cavity 5. For example, micromechanical component 1 is designed in such a way that substrate 3 and cap 7 additionally together enclose a second cavity. The second cavity, however, is not shown in FIG. 1 and in FIG. 2.

For example, a first pressure prevails in first cavity 5, in particular when access opening 11 is sealed, as shown in FIG. 2. Moreover, a first gas mixture having a first chemical composition is enclosed in first cavity 5. In addition, for example, a second pressure prevails in the second cavity, and a second gas mixture having a second chemical composition is enclosed in the second cavity. Access opening 11 is preferably situated in substrate 3 or in cap 7. In the present exemplary embodiment, access opening 11 is situated in cap 7 by way of example. According to the present invention, however, it may also be alternatively provided that access opening 11 is situated in substrate 3.

It is provided, for example, that the first pressure in first cavity 5 is lower than the second pressure in the second cavity. It is also provided, for example, that a first micromechanical sensor unit for rotation rate measurement, which is not shown in FIG. 1 and FIG. 2, is situated in first cavity 5, and a second micromechanical sensor unit for acceleration measurement, which is not shown in FIG. 1 and FIG. 2, is situated in the second cavity.

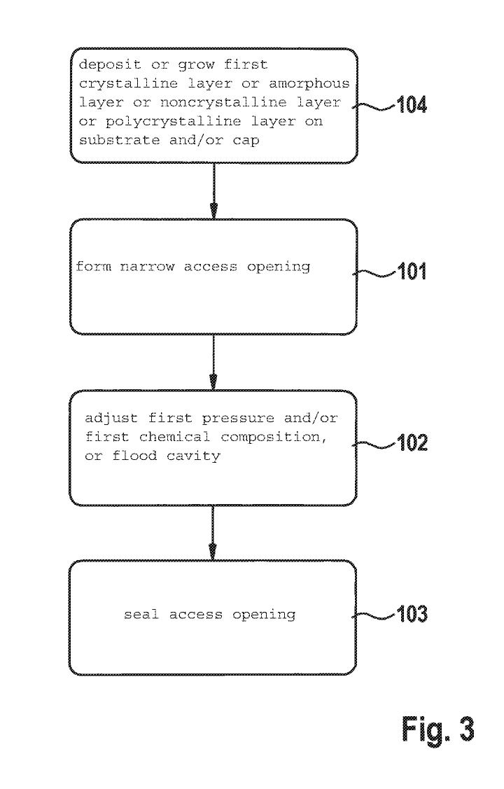

FIG. 3 shows a method for manufacturing micromechanical component 1 according to one exemplary specific embodiment of the present invention in a schematic representation. In this method,

in a first method step 101, in particular narrow access opening 11 connecting first cavity 5 to surroundings 9 of micromechanical component 1 is formed in substrate 3 or in cap 7. FIG. 1 shows micromechanical component 1 after first method step 101 by way of example. Moreover,

in a second method step 102, the first pressure and/or the first chemical composition in first cavity 5 is adjusted, or first cavity 5 is flooded with the desired gas and the desired internal pressure via the access channel. Furthermore, for example,

in a third method step 103, access opening 11 is sealed by introducing energy or heat with the aid of a laser into an absorbing part 21 of substrate 3 or cap 7. Alternatively, for example, it is also provided that

in the third method step 103, the area around the access channel is preferably heated only locally by a laser, and the access channel is hermetically sealed. Thus, it is advantageously possible to also provide the method according to the present invention with energy sources other than with a laser for sealing access opening 11. FIG. 2 shows micromechanical component 1 after third method step 103 by way of example.

Chronologically after third method step 103, it is possible for mechanical stresses to occur in a lateral area 15, shown by way of example in FIG. 2, on a surface facing away from cavity 5 of cap 7 and in the depth perpendicularly to a projection of lateral area 15 onto the surface, i.e., along access opening 11 and in the direction of first cavity 5 of micromechanical component 1. These mechanical stresses, in particular local mechanical stresses, prevail in particular on and in the vicinity of an interface between a material area 13 of cap 7, which in third method step 103 transitions into a liquid aggregate state and after third method step 103 transitions into a solid aggregate state and seals access opening 11, and a remaining area of cap 7, which remains in a solid aggregate state during third method step 103. In FIG. 2, material area 13 of cap 7 sealing access opening 11 is to be regarded only schematically or is shown only schematically, in particular with respect to its lateral extension or form, extending in particular in parallel to the surface, and in particular with respect to its expansion or configuration perpendicularly to the lateral extension, running in particular perpendicularly to the surface.

As shown in FIG. 3 by way of example,

in a fourth method step 104, a first crystalline layer or a first amorphous layer or a first nanocrystalline layer or a first polycrystalline layer is deposited on or grown on a surface of substrate 3 or of cap 7 and/or

in a fifth method step a substrate 3 including a second crystalline layer and/or a second amorphous layer and/or a second nanocrystalline layer and/or a second polycrystalline layer, and/or a cap 7 including the second crystalline layer and/or the second amorphous layer and/or the second nanocrystalline layer and/or the second polycrystalline layer is provided.

In other words, in fourth method step 104, for example, a layer of a second crystalline, amorphous, nanocrystalline or preferably polycrystalline material or a material packet of the cited materials or layers is applied to a crystalline substrate material or cap material or to the sensor wafer or to the cap wafer. This occurs, for example, at least partially in a fourth method step 104, which chronologically proceeds first method step 101. In other words, it is provided, for example, that fourth method step 104 is carried out chronologically before first method step 101. According to the present invention, it is alternatively or additionally provided, however, that fourth method step 104 is carried out chronologically after third method step 103.

In addition, in a sixth method step, for example, a third crystalline layer or a third amorphous layer or a third nanocrystalline layer or a third polycrystalline layer is deposited on or grown on the first crystalline layer or on the first amorphous layer or on the first nanocrystalline layer or on the first polycrystalline layer, in particular, for constructing a material packet or layer packet. In addition, in a seventh method step, for example, a fourth crystalline layer or a fourth amorphous layer or a fourth nanocrystalline layer or a fourth polycrystalline layer is deposited on or grown on the third crystalline layer or on the third amorphous layer or on the third nanocrystalline layer or on the third polycrystalline layer. Furthermore, in an eighth method step, for example, a fifth crystalline layer or a fifth amorphous layer or a fifth nanocrystalline layer or a fifth polycrystalline layer is also deposited on or grown on the fourth crystalline layer or on the fourth amorphous layer or on the fourth nanocrystalline layer or on the fourth polycrystalline layer.

When using a layer packet, it is in particular also provided, for example, that in third method step 103 only the uppermost layer is fused in a target manner.

Furthermore, it is provided, for example, that instead of a crystalline substrate material or cap wafer or sensor wafer, an amorphous, nanocrystalline or preferably polycrystalline substrate material or cap wafer or sensor wafer is utilized. For this purpose, the fifth method step, for example, is carried out. According to the present invention, it is provided, for example, that the fifth method step is carried out chronologically before the first method step.

Moreover, it is also provided, for example, that the crystalline, polycrystalline nanocrystalline or amorphous substrate material, the applied layer or the layer packet are doped. For this purpose,

substrate 3 or cap 7 and/or

the first crystalline layer or the first amorphous layer or the first nanocrystalline layer or the first polycrystalline layer and/or

the second crystalline layer and/or the second amorphous layer and/or the second nanocrystalline layer and/or the second polycrystalline layer and/or

the third crystalline layer or the third amorphous layer or the third nanocrystalline layer or the third polycrystalline layer and/or

the fourth crystalline layer or the fourth amorphous layer or the fourth nanocrystalline layer or the fourth polycrystalline layer and/or
the fifth crystalline layer or the fifth amorphous layer or the fifth nanocrystalline layer or the fifth polycrystalline layer
   are doped, for example, in a ninth method step. It is provided, in particular, for example, that the cap wafer or the sensor wafer or substrate 3 or cap 7 are doped with boron. Furthermore, it is provided, for example, that the ninth method step is carried out chronologically before the first method step. Moreover, it is also provided, for example, that the ninth method step is carried out chronologically after the fifth method step.

In addition, it is provided, for example, that a natural oxide is removed or that passivation against renewed oxidation occurs. In this case, it is provided, for example, that the natural oxide is removed from the cap wafer or sensor wafer or from cap 7 or from substrate 3. Furthermore, it is also provided, for example, that the cap wafer or the sensor wafer or substrate 3 or cap 7 is protected against renewed oxidation.

In addition, it is also provided, for example, that the doped or undoped substrate material or the applied material or material packet or the substrate material and the applied material or material packet are fused during the local heating process, for example, during third method step 103.

Finally, it is provided that the micromechanical component 1 manufactured with the method according to the present invention includes, for example, various cap materials, multilayer caps or modified cap materials, and which differ, for example, from the related art.

What is claimed is:

1. A method for manufacturing a micromechanical component including a substrate, and a cap connected to the substrate, the cap together with the substrate enclosing a first cavity, a first pressure prevailing and a first gas mixture having a first chemical composition being enclosed in the first cavity, the method comprising:
in a first method step, forming, in the substrate or the cap, an access opening connecting the first cavity to surroundings of the micromechanical component;
in a second method step, adjusting, in the first cavity, at least one of the first pressure and the first chemical composition;
in a third method step, sealing the access opening by introducing energy or heat into an absorbing part of the substrate or the cap, with the aid of a laser; and
at least one of:
in a fourth method step, deposing or growing on a surface of the substrate or of the cap, one of a first crystalline layer, a first amorphous layer, a first nanocrystalline layer, or a first polycrystalline layer; and
in a fifth method step, providing at least one of: i) the substrate including at least one of a second crystalline layer, a second amorphous layer, a second nanocrystalline layer, a second polycrystalline layer, and ii) the cap including at least one of the second crystalline layer, the second amorphous layer, the second nanocrystalline layer, and the second polycrystalline layer.

2. The method as recited in claim 1, further comprising:
in a sixth method step, depositing or growing, on the one of the first crystalline layer, first amorphous layer, first nanocrystalline layer, or first polycrystalline layer, one of a third crystalline layer, a third amorphous layer, a third nanocrystalline layer, or a third polycrystalline layer.

3. The method as recited in claim 2, further comprising:
in a seventh method step, deposition or growing, on the one of the third crystalline layer, third amorphous layer, third nanocrystalline layer, or third polycrystalline layer, one of a fourth crystalline layer, a fourth amorphous layer, a fourth nanocrystalline layer, or a fourth polycrystalline layer.

4. The method as recited in claim 3, further comprising:
in an eighth method step, depositing or growing, on the one of the a fourth crystalline layer, fourth amorphous layer, fourth nanocrystalline layer, or a fourth polycrystalline layer, one of a fifth crystalline layer, a fifth amorphous layer, a fifth nanocrystalline layer, or a fifth polycrystalline layer.

5. The method as recited in claim 4, further comprising:
in a ninth method step, doping at least one of: i) the substrate, ii) the cap, iii) the one of the first crystalline layer, first amorphous layer, first nanocrystalline layer, or first polycrystalline layer, iv) the at least one of the second crystalline layer, second amorphous layer, second nanocrystalline layer, and second polycrystalline layer, v) the one of the third crystalline layer, third amorphous layer, third nanocrystalline layer, or third polycrystalline layer, vi) the one of the fourth crystalline layer, fourth amorphous layer, fourth nanocrystalline layer, or fourth polycrystalline layer, and vii) the one of the fifth crystalline layer, fifth amorphous layer, fifth nanocrystalline layer, or fifth polycrystalline layer.

6. The method as recited in claim 4, further comprising:
in a tenth method step, at least one of:
removing an oxide situated at least partially on or in at least one of: i) the substrate, ii) the cap, iiiiii) the one of the first crystalline layer, first amorphous layer, first nanocrystalline layer, or first polycrystalline layer, iv) the at least one of the second crystalline layer, second amorphous layer, second nanocrystalline layer, and second polycrystalline layer, v) the one of the third crystalline layer, third amorphous layer, third nanocrystalline layer, or third polycrystalline layer, vi) the one of the fourth crystalline layer, fourth amorphous layer, fourth nanocrystalline layer, or fourth polycrystalline layer, and vii) the one of the fifth crystalline layer, fifth amorphous layer, fifth nanocrystalline layer, or fifth polycrystalline layer; and
passivating, against oxidation, at least one of:
i) the substrate, ii) the cap, iii) the one of the first crystalline layer, first amorphous layer, first nanocrystalline layer, or first polycrystalline layer, iv) the at least one of the second crystalline layer, second amorphous layer, second nanocrystalline layer, and second polycrystalline layer, v) the one of the third crystalline layer, third amorphous layer, third nanocrystalline layer, or third polycrystalline layer, vi) the one of the fourth crystalline layer, fourth amorphous layer, fourth nanocrystalline layer, or fourth polycrystalline layer, and vii) the one of the fifth crystalline layer, fifth amorphous layer, fifth nanocrystalline layer, or fifth polycrystalline layer.

7. A micromechanical component, comprising:
a substrate; and
a cap connected to the substrate, the cap, together with the substrate, enclosing a first cavity, a first pressure prevailing and a first gas mixture having a first chemical composition being enclosed in the first cavity, one of the substrate or the cap including a sealed access opening;
wherein at least one of: i) the micromechanical component includes one of a first crystalline layer, a first amorphous layer, a first nanocrystalline layer, or a first polycrystalline layer, deposited on or grown on a surface of the substrate or of the cap, and ii) one of the the substrate or the cap includes at least one of a second crystalline layer, a second amorphous layer, a second nanocrystalline layer, and a second polycrystalline layer.

8. The micromechanical component as recited in claim 7, wherein the micromechanical component includes one of: i) a third crystalline layer, a third amorphous layer, a third nanocrystalline layer, or a third polycrystalline layer deposited on or grown on the first crystalline layer or on the first amorphous layer or on the first nanocrystalline layer or on the first polycrystalline layer.

9. The micromechanical component as recited in claim 7, wherein the cap, together with the substrate, encloses a second cavity, a second pressure prevailing and a second gas mixture having a second chemical composition being enclosed in the second cavity.

10. The micromechanical component as recited in claim 9, wherein the first pressure is lower than the second pressure, a first sensor unit for rotation rate measurement being situated in the first cavity and a second sensor unit for acceleration measurement being situated in the second cavity.
